(19) United States
(12) Patent Application Publication
(10) Pub. No.: US 2009/0265602 A1
(43) Pub. Date: Oct. 22, 2009

(54) LIQUID CONTAINER

(76) Inventor: Shuichi Nakano, Hitachi-shi (JP)

Correspondence Address: STROOCK & STROOCK & LAVAN LLP, 180 MAIDEN LANE, NEW YORK, NY, 10038, US

(21) Appl. No.: 12/402,876

(22) Filed: Mar. 12, 2009

(30) Foreign Application Priority Data
Mar. 18, 2008 (JP) 2008-69078
Mar. 4, 2009 (JP) 2009-50961

(51) Int. Cl. H03M 13/00; G06F 11/07

(52) U.S. Cl. 714/799; 714/E11.024

(57) ABSTRACT

When a semiconductor storage device 10 receives write data, an error detection operation decoder 150 in the semiconductor storage device 10 determines whether any error arises in the received write data. Upon detection of an error in the received write data, the error detection operation decoder 150 does not send a write enable signal WEN to a write-read controller 140. The write data with the detected error is accordingly not written into a memory array 100.

### BACKGROUND OF THE INVENTION

The present invention relates to a liquid container equipped with a storage device, as well as to an access control method of controlling an access to the storage device mounted on the liquid container.

Liquid containers, such as ink cartridges, equipped with storage devices have been turned into actual utilization. One proposed technique for enhancing the reliability of data stored in the storage device generates an error correction code and stores the generated error correction code in the storage device in the course of a data writing operation into the storage device. On the occasion of reading data from the storage device, the proposed technique refers to the error correction code stored in the storage device and identifies detection of an error or no error arising in the read data.

Registration of the error correction code in the storage device, however, undesirably increases the required memory capacity of the storage device and the size of the storage device. This leads to a cost increase in low-capacity storage devices. In the recent systems, data stored in the storage device has relatively high reliability. In a system with a mechanical contact on a communication path, an error arising in data is mainly ascribed to a trouble on the communication paths, for example, contact failure or noise.

These problems are not characteristic of the storage device included in the liquid container but are commonly found in various storage devices including standalone storage devices.

### SUMMARY OF THE INVENTION

In order to solve at least part of the problems mentioned above, there would be a demand for enhancing the reliability of data stored in a storage device.

The present invention accomplishes at least part of the demand mentioned above and the other relevant demands by variety of configurations discussed below.

According to a first aspect, the invention is directed to a liquid container equipped with a storage device. The liquid container has: a storage element configured to store data; an error detection circuit configured to receive write data as a writing object, which is to be written into the storage element, and detect an error in the received write data; and a read-write controller configured to control a data reading operation and a data writing operation from and into the storage element and to prohibit the data writing operation of the received write data into the storage element, in response to detection of an error in the received write data by the error detection circuit.

Upon detection of an error in the received write data, the liquid container according to the first aspect of the invention prohibits the data writing operation of the received write data into the storage element. This arrangement desirably enhances the reliability of data stored in the storage device.

In one preferable embodiment of the invention, the liquid container of the first application further has an error detection result storage module configured to store a result of error detection. The liquid container of this arrangement can readily detect the occurrence of an error in the write data based on the result stored in the error detection result storage module without requiring actual verification of the data stored in the storage device.

In one preferable application of the liquid container according to the first aspect of the invention, the storage element is a sequential access-type storage element. In the case of detection of an error in the received write data by the error detection circuit, the read-write controller prohibits the data writing operation of subsequently received write data into the storage element. The liquid container of this arrangement effectively prevents and restrains wrong write data from being written into the storage element.

In another preferable application of the liquid container according to the first aspect of the invention, the storage element is a sequential access-type storage element. In the case of detection of an error in the received write data by the error detection circuit, the read-write controller allows the data writing operation of subsequently received write data with detection of no error by the error detection circuit into the storage element. The liquid container of this arrangement effectively prevents and restrains wrong write data from being written into the storage element, while allowing normal write data to be written into the storage element.

In still another preferable application of the liquid container according to the first aspect of the invention, a write command and an error detection code are allocated to the write data. The error detection circuit refers to the write command to identify the received write data as the writing object to be written into the storage element, while referring to the error detection code to detect an error in the received write data. The liquid container of this arrangement can detect an error in the data with the write command.

According to a second aspect, the invention is also directed to a system configured to include a liquid container equipped with a storage device and a computing machine designed to perform a data writing operation and a data reading operation into and from the storage device.

The computing machine has: an error code allocation circuit configured to allocate an error code to data, which is to be written into the storage device, and generate write data; and a transmission module configured to send the generated write data to the storage device.

The liquid container has: a storage element configured to store data; an error detection circuit configured to receive the write data and detect an error in the received write data; and a read-write controller configured to control a data reading operation and a data writing operation from and into the storage element and to prohibit the data writing operation of the received write data into the storage element, in response to detection of an error in the received write data by the error detection circuit.

In the system according to the first aspect of the invention, the computing machine allocates the error code to the data that is to be written into the storage device. Upon detection of an error in the received write data, the liquid container prohibits the data writing operation of the received write data into the storage element. This arrangement desirably enhances the reliability of data stored in the storage device.

In one preferable application of the system according to the second aspect of the invention, the liquid container further has an error detection result storage module configured to store a result of error detection. When the result stored in the error detection result storage module in the liquid container represents detection of an error, the computing machine sends all write data, which are writable into the storage device, to the storage device. The system of this arrangement can update the data stored in the storage device to correct data without requiring actual verification of the data stored in the storage device.

In another preferable application of the system according to the second aspect of the invention, the storage element of the liquid container is a sequential access-type storage element. The error code allocation circuit of the computing machine generates transmission code data with an erroneous code. The computing machine sends the generated transmission code data to the storage device until reaching a desired address in the storage device, and sends the write data to the storage device at the desired address in the storage device. The system of this arrangement desirably enhances the speed of the data writing operation at a desired address in the storage device including the sequential access-type storage element.

According to a third aspect, the invention is further directed to an access control method of controlling an access to a storage device included in a liquid container. The access control method receives write data as a writing object, which is to be written into a storage element provided in the storage device, and detects an error in the received write data. The access control method prohibits a data writing operation of the received write data into the storage element, in response to detection of an error in the received write data.

Upon detection of an error in the received write data, the access control method according to the third aspect of the invention prohibits the data writing operation of the received write data into the storage element. This arrangement desirably enhances the reliability of data stored in the storage device. The access control method according to the third aspect of the invention may be actualized in any of various applications, like the liquid container according to the first aspect of the invention. The access control method according to the third aspect of the invention may also be actualized in the form of a computer program or a computer program product recorded in a computer readable medium, such as a CD, a DVD, or an HDD.

According to a fourth aspect, the invention is also directed to a storage device including: a storage element configured to store data; an error detection circuit configured to receive write data as a writing object, which is to be written into the storage element, and detect an error in the received write data; and a read-write controller configured to control a data reading operation and a data writing operation from and into the storage element and to prohibit the data writing operation of the received write data into the storage element, in response to detection of an error in the received write data by the error detection circuit.

Upon detection of an error in the received write data, the storage device according to the fourth aspect of the invention prohibits the data writing operation of the received write data into the storage element. This arrangement desirably enhances the reliability of data stored in the storage device.

According to a fifth aspect, the invention is further directed to a circuit board that includes: a semiconductor device having: a storage element configured to store data; an error detection circuit configured to receive write data as a writing object, which is to be written into the storage element, and detect an error in the received write data; and a read-write controller configured to control a data reading operation and a data writing operation from and into the storage element and to prohibit the data writing operation of the received write data into the storage element, in response to detection of an error in the received write data by the error detection circuit; and one or multiple external terminals electrically connected with the semiconductor device.

Upon detection of an error in the received write data, the circuit board according to the fifth aspect of the invention prohibits the data writing operation of the received write data into the storage element. This arrangement desirably enhances the reliability of data stored in the storage device.

### BRIEF DESCRIPTION OF THE DRAWINGS

FIG. 1 is a functional block diagram showing the internal structure of a semiconductor storage device in a first embodiment of the invention;

FIG. 2 is a schematic explanatory view showing one example of a write data array input into the semiconductor storage device in the embodiment;

FIG. 3 is a schematic explanatory view showing a system including a host computer as a computing machine and semiconductor storage devices in the embodiment;

FIG. 4 is a flowchart showing a processing routine executed in the semiconductor storage device at the time of access control for the semiconductor storage device in the embodiment;

FIG. 5 is a flowchart showing a processing routine executed in the host computer at the time of access control for the semiconductor storage device in the embodiment;

FIG. 6 is a flowchart showing a processing routine executed with reference to an error detection result in the host computer at the time of access control for the semiconductor storage device in the embodiment;

FIG. 7 is a flowchart showing a processing routine executed for quick data writing at a desired address in the host computer at the time of access control for the semiconductor storage device in the embodiment;

FIG. 8 is an explanatory view showing one example of a liquid container;

FIG. 9 is a functional block diagram showing the internal structure of a semiconductor device in a second embodiment of the invention;

FIG. 10 is an explanatory view showing the schematic structure of an ink cartridge as a liquid container;

FIG. 11 is an explanatory view showing the structure of a printing apparatus and connection of the printing apparatus with the ink cartridge in the embodiment;

FIG. 12 is a flowchart showing a processing routine executed in the semiconductor device at the time of access control for the semiconductor device in the embodiment;

FIG. 13 is a flowchart showing a processing routine executed in the printing apparatus as a host computer at the time of write access to the semiconductor device in the embodiment; and

FIG. 14 is a flowchart showing a processing routine executed with reference to an error detection result in the printing apparatus at the time of access to detect an error representing a failure of writing into the semiconductor device due to a data error.

### DETAILED DESCRIPTION OF THE PREFERRED EMBODIMENTS

### First Embodiment

A semiconductor storage device and an access control method for the semiconductor storage device are described below as a first embodiment of the invention with reference to the accompanied drawings.

### [Structure of Semiconductor Storage Device]

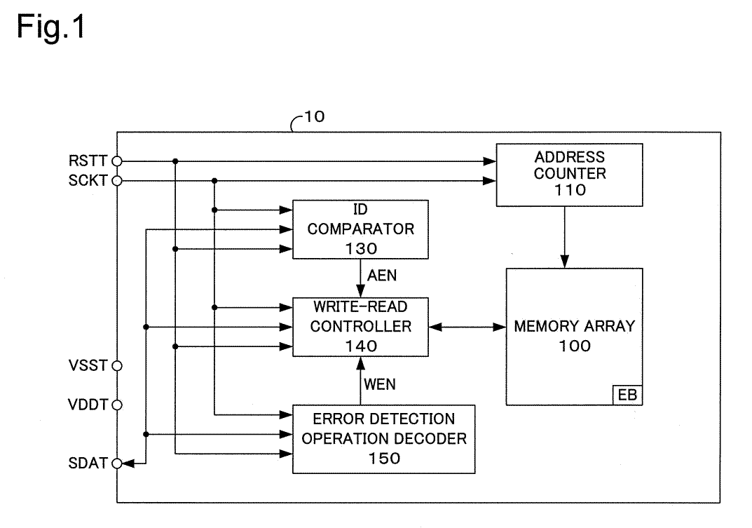

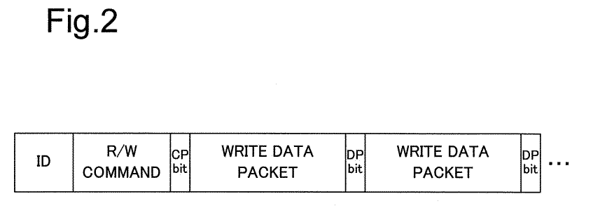

The structure of a semiconductor storage device of this embodiment is discussed with reference to FIGS. 1 and 2. FIG. 1 is a functional block diagram showing the internal structure of the semiconductor storage device in the embodiment of the invention. FIG. 2 is a schematic explanatory view showing one example of a write data array input into the semiconductor storage device in the embodiment.

A semiconductor storage device 10 of the embodiment is constructed as a sequential access-type storage device that does not require external input of address data for specifying an address of access destination. The semiconductor storage device 10 includes a memory array 100, an address counter 110, an ID comparator 130, a write-read controller 140, and an error detection operation decoder 150. The respective circuits are interconnected by bidirectional bus signal lines. The combination of the write-read controller 140 with at least the ID comparator 130 and the error detection operation decoder 150 may be referred to as a memory controller in the description herein.

The memory array 100 represents a storage area having the EEPROM characteristics of enabling data to be electrically written and erased. The memory array 100 includes a number of data cells (memory cells), each having the capacity for storing 1-bit information. A specific address unit of the memory array 100 is, for example, eight addresses (addresses of 8-bit data capacity) per row. In the structure having sixteen data cells (sixteen words) per column, the memory array 100 is capable of totally storing data of 16 words×8 bits (=128 bits). Part of the memory array 100 forms an error detection result storage area EB for storing a result of error detection whether an error is detected or not. The error detection result storage area EB is, for example, a 1-bit area. In response to detection of an error in write data by the error detection operation decoder 150, a value ‘1’ is recorded into the error detection result storage area EB via the write-read controller 140. In response to detection of no error in write data by the error detection operation decoder 150, on the other hand, a value ‘0’ is recorded into the error detection result storage area EB via the write-read controller 140. The error detection result storage area EB may be provided independently of the memory array 100 as a separate memory unit, such as a register. The error detection result storage area EB is reset to ‘0’ on completion of a writing process of the write data with detection of an error.

The memory array 100 of this embodiment apparently has multiple rows of the 8-bit capacity. Each of the multiple rows is, however, not an independent data cell row, but rather one long data cell row is folded in the unit of 8 bits. Only as a matter of convenience, a row starting from a 9^{th} bit is called a 2^{nd} byte or row, and a row starting from a 17^{th} bit is called a 3^{rd} byte or row. A sequential access from the top bit is thus required to make access to a desired address in the memory array 100. The sequential access system accordingly does not allow a direct access to a desired address, which is allowed in the random access system.

In the memory array 100, word lines and bit (data) lines are connected to the respective data cells. The data writing procedure selects a word line (row) corresponding to a certain data cell (by application of a selected voltage) and applying a write voltage into a corresponding bit line to write data into the certain data cell. The data reading procedure selects a word line (row) corresponding to a certain data cell, connects a corresponding bit line with the write-read controller 140, and identifies detection or no detection of electric current to read data (1 or 0) from the certain data cell. The specific address unit of this embodiment represents the number of addresses (the number of data cells), which enable data to be written in by application of a write voltage onto one word line.

The memory array 100 has a column selection circuit (not shown) that sequentially connects the columns (bit lines) with the write-read controller 140, in response to an external clock pulse number counted by the address counter 110. The memory array 100 also has a row selection circuit (not shown) that sequentially applies a selected voltage to the rows (word lines), in response to the external clock pulse number counted by the address counter 110. As discussed above, the semiconductor storage device 10 of the embodiment does not make access to the memory array 100 based on the address data but rather makes access to a desired address according to the clock pulse number counted by the address counter 110.

The address counter 110 is connected with a reset signal terminal RSTT, a clock signal terminal SCKT, the write-read controller 140, and the memory array 100. The address counter 110 is reset to an initial value by setting 0 (or a low level) to a reset signal input via the reset signal terminal RSTT. The address counter 110 counts the clock pulse number (increments the count) synchronously with a fall of each clock pulse input via the clock signal terminal SCKT after setting 1 to the reset signal.

The address counter 110 of this embodiment is an 8-bit address counter that stores eight clock pulse numbers corresponding to the number of data cells (the number of bits) per row in the memory array 100. The initial value of the address counter 110 may be any value related to a head position of the memory array 100 and is typically equal to 0.

The ID comparator 130 is connected with the clock signal terminal SCKT, a data signal terminal SDAT, and the reset signal terminal RSTT and identifies whether identification data included in an input data array input via the data signal terminal SDAT is identical with identification data stored in the memory array 100. According to a concrete procedure, the ID comparator 130 obtains data of first 3 bits or identification data, which is included in an operation code input after a reset signal RST, from the write-read controller 140. The ID comparator 130 has a 3-bit register (not shown) for storing identification data of first 3 bits included in an input data array shown in FIG. 2, as well as a 3-bit register (not shown) for storing identification data of upper-most 3 bits obtained from a specified address in the memory array 100 via the write-read controller 140. The ID comparator 130 compares values in the two registers with each other, so as to determine matching or mismatching of the two identification data. When the two identification data are identical with each other, the ID comparator 130 sends an access enable signal AEN to the write-read controller 140. The ID comparator 130 clears the two registers, in response to input of the reset signal RST (RST=0 or low)

The write-read controller 140 is connected with the ID comparator 130, the error detection operation decoder 150, the clock signal terminal SCKT, the data signal terminal SDAT, and the reset signal terminal RSTT. The write-read controller 140 constructed as a circuit waits for input of a write enable signal WEN from the error detection operation decoder 150 and changes over the internal operation of the semiconductor storage device 10 to a writing operation. In the case of no input of the write enable signal WEN, on the contrary, the write-read controller 140 changes over the internal operation of the semiconductor storage device 10 to a reading operation.

The write-read controller 140 performs changeover control of a data transfer direction relative to the memory array 100 and a data transfer direction relative to the data signal terminal SDAT (more precisely, relative to a signal line connecting with the data signal terminal SDAT) according to input or no input of the write enable signal WEN. The write-read controller 140 has an 8-bit register (not shown) for temporarily storing 8-bit write data after an operation code included in write data that is input from the data signal terminal SDAT via a connecting input signal line, as well as a register (not shown) for storing data read from the memory array 100.

A data array (MSB) input via the input signal line from the data signal terminal SDAT is sequentially stored in the 8-bit register until all 8 bits are occupied. When all 8-bits are occupied, the stored 8-bit data is written into the memory array 100.

At a power-ON time of the semiconductor storage device 10 or at a reset time when the semiconductor storage device 10 falls into a reset state in response to input of a reset signal (0), the write-read controller 140 sets the data transfer direction relative to the memory array 100 to a reading direction, while making the input signal line connecting with the data signal terminal SDAT high impedance to prohibit data transfer relative to the data signal terminal SDAT. This state is kept until input of the write enable signal WEN from the error detection operation decoder 150. Data of first 4 bits in a data array input via the data signal terminal SDAT after a reset signal (1) for cancelling the reset state are not written into the memory array 100, while data stored in first 4 bits in the memory array 100 are transferred to the ID comparator 130. The first 4 bits in the memory array 100 are thus kept in a read only state.

The write-read controller 140 waits for both input of the write enable signal WEN from the error detection operation decoder 150 and input of the access enable signal AEN from the ID comparator 130 and starts a writing operation. In the case of no input of the write enable signal WEN from the error detection operation decoder 150, on the contrary, the write-read controller 140 waits for input of the access enable signal AEN from the ID comparator 130 and starts a reading operation.

On the occasion of the writing operation, the write-read controller 140 changes over the data transfer direction of a bus signal line to a writing direction, in response to input of a specific number of clock pulses corresponding to an initial address in a writable area. In response to input of a specified number of clock pulses corresponding to an end address in the writable area, the write-read controller 140 changes over the data transfer direction of the bus signal line to a reading direction. A write voltage required for the writing operation is generated, for example, by a charge pump circuit (not shown).

On the occasion of the reading operation, the write-read controller 140 changes over the data transfer direction of the bus signal line to the reading direction, in response to input of the specific number of clock pulses corresponding to the initial address in the writable area.

In the presence of an error in write data, the procedure of this embodiment does not perform the writing operation of the write data into the memory array 100. When an error occurs in a write data array input from a host computer due to, for example, an external noise, the procedure of this embodiment utilizes an error correction encoding technique and does not perform the writing operation of at least the write data array with the error into the memory array 100. This aims to enhance the reliability of data stored in the memory array 100. This function is provided by the error detection operation decoder 150 discussed below.

The error detection operation decoder 150 is connected with the reset signal terminal RSTT and the write-read controller 140 via signal lines. The error detection operation decoder 150 obtains read/write control information (5-bit information following the 3-bit ID information) included in data array input via the data signal terminal SDAT, synchronously with 4^{th} through 8^{th} clock pulses after input of the reset signal RST. The error detection operation decoder 150 performs error detection with the input ID information, the read/write control information (R/W command), and a 9^{th} bit or a command parity bit (CP bit) following the 5-bit write-read control information. When a parity value represented by the command parity bit (CP bit) is identical with a parity value computed from the ID information and the read/write control information, the error detection operation decoder 150 identifies the read/write control information as a valid command. When the two parity values are not identical but are different, on the other hand, the error detection operation decoder 150 identifies the write-read control information as an invalid command. When the write-read control information is identified as a valid command and represents a write command, the error detection operation decoder 150 subsequently performs error detection with regard to the input write data array. When the write-read control information is identified as an invalid command or represents a read command, on the other hand, the error detection operation decoder 150 does not perform error detection with regard to the input write data array.

When the input data array is write data, the error detection operation decoder 150 performs error detection with each 8-bit write data packet and a subsequent 1-bit data parity bit (DP bit) shown in FIG. 2. When a parity value represented by the data parity bit (DP bit) is identical with a parity value computed from the write data packet, the error detection operation decoder 150 determines that no error arises in the write data packet. When the two parity values are not identical but are different, on the other hand, the error detection operation decoder 150 determines that an error arises in the write data packet. The error detection of data with the parity bit is known in the art and is thus not specifically explained here. Upon determination that no error arises in the write data packet, the error detection operation decoder 150 outputs the write enable signal WEN to the write-read controller 140 and writes the value ‘0’ into the error detection result storage area EB. Upon determination that an error arises in the write data packet, on the other hand, the error detection operation decoder 150 does not output the write enable signal WEN and writes the value ‘1’ into the error detection result storage area EB.

### [System Configuration Including Semiconductor Storage Device]

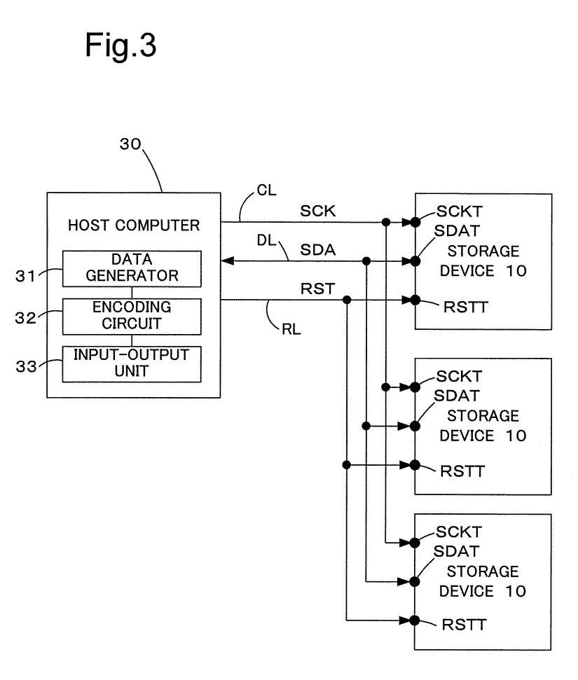

FIG. 3 is a schematic explanatory view showing a system including a host computer as a computing machine and semiconductor storage devices in the embodiment.

A host computer 30 is connected with multiple semiconductor storage devices 10 via a clock signal line CL, a data signal line DL, and a reset signal line RL by the bus method. The respective semiconductor storage devices 10 are connected to the host computer 30 via the common signal lines. The host computer 30 includes a data generator 31, an encoding circuit 32, and an input-output unit 33, which are interconnected by internal wiring. The data generator 31 generates a data array including identification information (ID) for identifying the semiconductor storage device 10 as a writing destination, a write command, and data packets as a writing object. In the configuration of this embodiment, each of the semiconductor storage devices 10 is a sequential access-type storage device, and data is written into the semiconductor storage device 10 in the unit of 1 byte (8 bits). The data array generated accordingly includes one or multiple 8-bit write data packets corresponding to one or multiple rows in the memory array 100. Based on object data to be written, a data array is generated such as to include multiple write data packets from a writing start row to a specific row including a storage position (address) of the object data. In order to complete writing object data by one writing operation, a storage area of each rewritable data (update data) may be allocated in advance to the same row in the memory array 100.

The encoding circuit 32 utilizes the identification information and the read/write (R/W) command to generate a command parity bit (CP bit) and inserts the generated command parity bit (CP bit) in a 1-bit position immediately after the read/write command, so as to generate encoded data of the data array. The encoding circuit 32 subsequently utilizes the one or multiple 8-bit write data packets to generate corresponding one or multiple data parity bits (DP bit) and inserts each of the generated data parity bits (DP bit) in a 1-bit position immediately after each 8-bit write data packet, so as to generate encoded data of the data array. According to the concrete structure shown in FIG. 2, the generated data array includes identification information in the first 3 bits, a read/write (R/W) command in the 4^{th} bit through the 8^{th} bit, a command parity bit (CP bit) in the 9^{th} bit, a first write data packet in the 10^{th} bit through the 17^{th} bit, a data parity bit (DP bit) in the 18^{th} bit, a second write data packet in the 19^{th} bit through the 26^{th} bit, and a data parity bit (DP bit) in the 27^{th} bit. The input-output unit 33 is connected with the clock signal line CL, the data signal line DL, and the reset signal line RL. The input-output unit 33 sends a clock signal SCK and a reset signal RST to each of the semiconductor storage devices 10 and transmits a data signal SDA to and from each of the semiconductor storage devices 10. In the configuration of this embodiment, the host computer 30 sends the generated data array bit by bit via the data signal line DL to the semiconductor storage device 10, synchronously with the clock signal SCK supplied to the semiconductor storage device 10 via the clock signal line CL. At the start of an access for writing or reading to the semiconductor storage device 10, the host computer 30 sends the reset signal (1) to the semiconductor storage device 10 to cancel the reset state of the semiconductor storage device 10 and performs data transfer synchronously with the clock signal as discussed above. At the end of the access for writing or reading to the semiconductor storage device 10, the host computer 30 sends the reset signal (0) to the semiconductor storage device 10 to make the semiconductor storage device 10 falls into the reset state.

### [Operations of Semiconductor Storage Device]

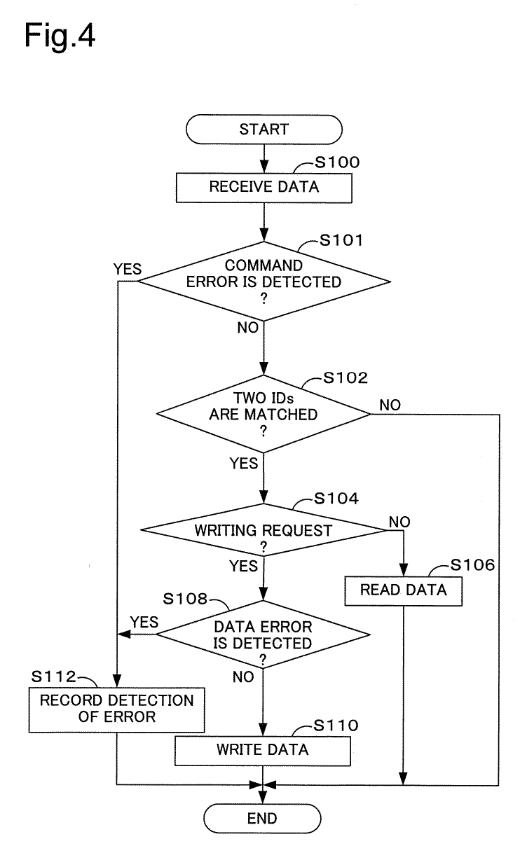

The operations of the semiconductor storage device 10 in the embodiment are described below with reference to FIG. 4. FIG. 4 is a flowchart showing a processing routine executed in the semiconductor storage device at the time of access control for the semiconductor storage device in the embodiment. The following description relates to the system including the multiple semiconductor storage devices 10 bus-connected with the host computer 30.

The semiconductor storage device 10 receives data from the host computer 30 (step S100) and identifies the validity of identification information ID bits and read/write command bits included in the received data (data array). According to a concrete procedure, the error detection operation decoder 150 compares a command parity bit (CP bit) included in the received data (data array) with the result of a parity operation based on the ID bits and the read/write command bits. The semiconductor storage device 10 detects no error in the received ID or read/write command in response to matching of the command parity bit with the result of the parity operation, while detecting an error in the received data in response to mismatching (step S101). Upon detection of an error (step S101: yes), the semiconductor storage device 10 writes the value ‘1’ into the error detection result storage area EB of the memory array 100 and exits from this processing routine. According to a concrete procedure, the error detection operation decoder 150 performs the writing operation into the memory array 100 via the write-read controller 140.

Upon identification of the validity of the ID and the read/write command (step S101: no), the semiconductor storage device 10 identifies whether the ID included in the received data (data array) is identical with its own ID (step S102). In the configuration of this embodiment, each of the semiconductor storage devices 10 is bus-connected with the host computer 30 via the common clock signal line CL, data signal line DL, and reset signal line RL. Data is accordingly sent from the host computer 30 to the respective semiconductor storage devices 10. According to the concrete procedure, the ID comparator 130 performs the ID matching by comparing the identification information ID included in the received data array with the identification information ID stored in the memory array 100 as discussed previously.

In the case of mismatching of the two IDs (step S102: no), the semiconductor storage device 10 identifies itself as no destination of the received data array and terminates the processing routine with regard to the current access.

In the case of matching of the two IDs (step S102: yes), on the other hand, the semiconductor storage device 10 determines whether there is a request for writing the receive data (step S104). According to the concrete procedure, the error detection operation decoder 150 analyzes the read/write command bits included in the received data array and identifies whether the analyzed read/write command bits represent a writing request or a reading request as described previously. In the case of matching of the two IDs, the ID comparator 130 sends the access enable signal AEN to the write-read controller 140. In the configuration of this embodiment, the ID comparator 130 sends the access enable signal AEN to the write-read controller 140. Alternatively the ID comparator 130 may send the access enable signal AEN to the error detection operation decoder 150. In the latter case, the error detection operation decoder 150 interprets the read/write command bits on reception of the access enable signal AEN.

Upon determination that there is no request for writing the received data but a reading operation is required (step S104: no), the semiconductor storage device 10 reads desired data from the memory array 100 (step S106) and exits from the processing routine (terminates the series of processing with regard to the current access). The write-read controller 140 reads the desired data from the memory array 100 according to the procedure discussed above.

Upon determination that there is a request for writing the received data (step S104: yes), on the other hand, the semiconductor storage device 10 detects an error of the data array if any (step S108). According to the concrete procedure, the error detection operation decoder 150 compares the data parity bit included in the received data array with the result of parity operation based on the write data and detects no error in the received data in response to matching of the command parity bit with the result of the parity operation, while detecting an error in the received data in response to mismatching as explained previously.

In response to detection of no error (step S108: no), the semiconductor storage device 10 writes the received data into the memory array 100 (step S110) and exits from this processing routine. According to the concrete procedure, the error detection operation decoder 150 sends the write enable signal WEN to the write-read controller 140, and the write-read controller 140 writes the received 8-bit data at a specific address (row) in the memory array 100 as discussed previously.

In response to detection of an error (step S108: yes), on the other hand, the semiconductor storage device 10 writes the value ‘1’ into the error detection result storage area EB of the memory array 100 and exits from this processing routine. According to the concrete procedure, the error detection operation decoder 150 performs the writing operation into the memory array 100 via the write-read controller 140 as discussed previously.

When the storage address of the write data in the memory array 100 is an upper address, the series of processing discussed above is repeated to a specific row including the storage address. In the case of detection of an error at step S108, one of the following available measures may be adopted for subsequent data writing:

(1) On detection of an error, the procedure accepts no subsequent writing request.

Upon determination of an error in currently processed write data, the procedure of this embodiment prohibits the write data with the detected error from being written into the memory array 100. The available measure (1) prohibits writing operations for any subsequently sent write data packets, as well as for a write data packet with a detected error. For example, in the event of an error arising in data due to a bad connection of a contact terminal between the host computer 30 and the semiconductor storage device 10, there is a high potential for an error arising in subsequent write data. This measure (1) effectively prevents wrong write data from being written into the memory array 100. The prohibition of writing the write data into the memory array 100 may be cancelled by, for example, entry of a specific command, a preset number of entries of a reset signal, a power-off operation, or elimination of an existing contact and reconstruction of a new contact (detachment and reattachment of the semiconductor storage device 10). According to a concrete procedure, in response to reception of an error detection result check command for obtaining a result of error detection, the error detection operation decoder 150 reads the storage value from the error detection result storage area EB in the memory array 100 via the write-read controller 140, and writes the value ‘0’ into the error detection result storage area EB. Alternatively the error detection operation decoder 150 may write the value ‘0’ into the error detection result storage area EB after output of a command for detaching and reattaching the semiconductor storage device 10 and detection of the actual detachment and reattachment of the semiconductor storage device 10.

(2) On detection of an error, the procedure prohibits a currently processed write data packet with the detected error from being written but accepts subsequent writing requests.

The available measure (2) prohibits a currently processed write data packet with a detected error from being written. The measure (2) performs error detection for each subsequently received write data packet, based on the received write data packet and a 1-bit data parity bit immediately after the received write data packet, and allows the subsequently received write data packet to be written in response to detection of no error. This measure is applicable to a procedure of sending a write data packet including an intentional error, in order to achieve a high-speed writing operation at a desired address.

On completion of writing operations for subsequently received write data packets, one modification of this measure may allow another trial for data writing at a specific address with failed data writing (allow the write data packet with the detected error to be tried again for data writing). Another trial for data writing may be performed, based on information that is recorded in the host computer 30 and identifies the specific address with failed data writing.

(3) On detection of an error, the procedure allows a currently processed write data packet with the detected error to be tried again for data writing.

The host computer 30 manages the information on the specific address in the memory array 100 of the semiconductor storage device 10 related to the write data packet with the detected error and failed data writing. The available measure (3) encodes the write data packet with the failed data writing and sends the encoded write data packet to the semiconductor storage device 10 to make another trial for data writing. This measure immediately takes action to eliminate a data writing error.

As discussed above, the semiconductor storage device 10 of the embodiment does not perform a writing operation into the memory array 100 on detection of an error in received write data. This arrangement desirably enhances the reliability of data stored in the semiconductor storage device 10.

The semiconductor storage device 10 has the error detection result storage area EB and thus readily identifies whether the data stored in any writable area of the memory array 100 is the valid data that is identical with the object data to be written, without performing actual verification by comparison between the write data and the existing data stored in the memory array 100. Even in the event of sudden power shutdown, the semiconductor storage device 10 of the embodiment can readily identify a writing request for write data with an error before the power shutdown. When the value stored in the error detection result storage area EB represents detection of an error in write data, the semiconductor storage device 10 immediately starts the writing operation for all the write data without performing the time-consuming verification. When the value stored in the error detection result storage area EB represents detection of no error in write data, the semiconductor storage device 10 restarts the writing operation for only the remaining unprocessed write data.

### [Operations of Host Computer]

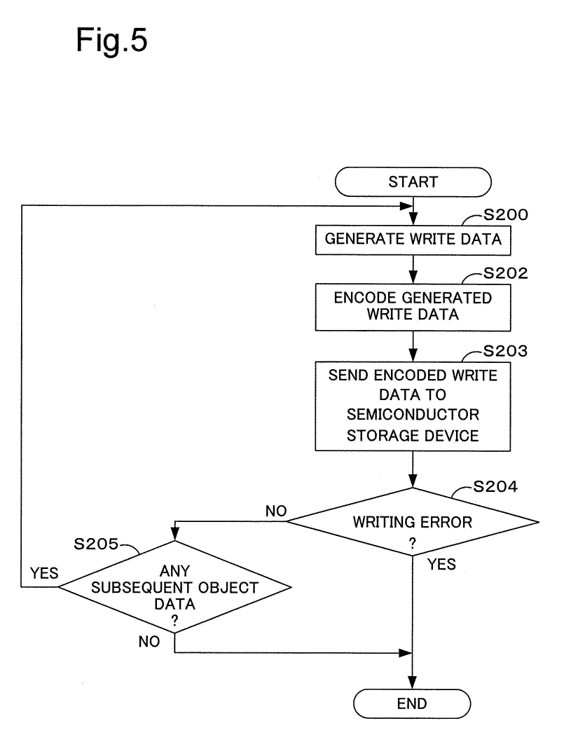

FIG. 5 is a flowchart showing a processing routine executed in the host computer at the time of access control for the semiconductor storage device in the embodiment. The host computer 30 generates write data, which is to be sent to the semiconductor storage device 10 in a current writing cycle, based on writing object data stored in a memory device (not shown) (step S200). In this embodiment, each writing cycle represents transmission of a 1-byte write data array corresponding to one row in the memory array 100. According to the concrete procedure, the data generator 31 generates the object data to be written in the form of a data array including identification information ID for identifying the semiconductor storage device 10 as a writing destination, a write command, and data packets as a writing object as discussed previously.

The host computer 30 subsequently encodes the generated write data (step S202). According to the concrete procedure, the encoding circuit 32 utilizes the read/write command to generate a command parity bit, utilizes each write data packet to generate a data parity bit, and inserts the command parity bit at a 9^{th} bit and the data parity bit at an 18^{th} bit from the head in the generated data array, so as to encode the data array as discussed previously.

The host computer 30 outputs the encoded write data array to the data signal line DL and sends the encoded write data array to the respective semiconductor storage devices 10 including the desired semiconductor storage device identified as the writing destination (step S203). In response to reception of a writing error signal from the semiconductor storage device 10 (step S204: yes), the host computer 30 exits from this processing routine. Namely even when there is any object data to be written in a subsequent writing cycle, the procedure of this embodiment does not perform a writing operation. The error detection operation decoder 150 in the semiconductor storage device 10 generates and sends the writing error signal to the host computer 30.

In response to reception of no writing error signal from the semiconductor storage device 10 (step S204: no), the host computer 30 determines whether there is any object data to be written in a subsequent writing cycle (step S205). In the absence of any object data (step S205: no), the processing flow terminates this processing routine.

In the present of any object data to be written in a subsequent writing cycle (step S205: yes), on the other hand, the processing flow returns to step S200 to generate another write data and repeats the series of processing up to step S204.

As discussed above, the host computer 30 sends the encoded write data to the semiconductor storage device 10. The combination of the host computer 30 with the semiconductor storage device 10 effectively prevents write data with an error to be written into the semiconductor storage device 10.

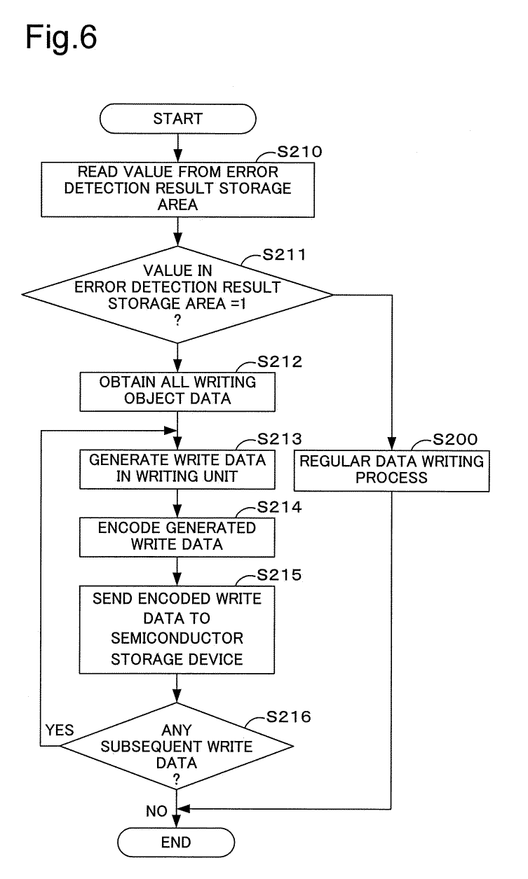

FIG. 6 is a flowchart showing a processing routine executed with reference to an error detection result in the host computer at the time of access control for the semiconductor storage device in the embodiment.

The following describes access control performed by the host computer 30 based on the error detection result. The host computer 30 communicates with the semiconductor storage device 10, for example, by the serial communication method. The host computer 30 outputs a data array including an ID of a desired semiconductor storage device as a writing destination and a write command to the data signal line DL and outputs clock pulses corresponding to a specific address of the error detection result storage area EB to the clock signal line CL, so as to read the value from the error detection result storage area EB (step S210). This identifies detection or no detection of an error in write data in the process of a writing operation to the desired semiconductor storage device. When the error detection result storage area EB is provided in a separate register outside the memory array 100, the host computer 30 makes access to the separate register to obtain the error detection result.

The host computer 30 identifies whether the value registered in the error detection result storage area EB is equal to ‘1’ (step S211). When the value in the error detection result storage area EB is equal to ‘1’ representing detection of an error (step S211: yes), the host computer 30 obtains all writing object data stored in a memory device (not shown) or all data corresponding to all writable areas in the memory array 100 (step S212). The data corresponding to the writable area is equivalent to writable data and is, for example, data relating to information on a liquid level (either a remaining amount or a consumed amount of a liquid) or a frequency of attachment of a liquid container to the host computer 30 (frequency of contacts between the semiconductor storage device 10 and the host computer 30).

The host computer 30 generates a command parity bit based on the read/write (R/W) command and sends the command parity bit to the semiconductor storage device 10. The host computer 30 then generates write data (write data packets) in the writing unit or in the byte unit (step S213). The host computer 30 subsequently generates a data parity bit based on a generated write data packet, inserts the generated data parity bit at the specified position mentioned above to encode the write data packet (step S214), and sends the encoded write data packet to the semiconductor storage device 10 (step S215). The detailed procedures of the respective steps have previously been described with reference to FIG. 5 and are thus not specifically explained here.

When there is any subsequent write data packet (step S216: yes), the processing flow returns to step S213. The host computer 30 repeats the processing of steps S213 to S215 until completion of writing of all the write data packets generated based on the obtained all writing object data. When there is no subsequent write data packet (step S216: no), the host computer 30 terminates this processing routine.

When the value in the error detection result storage area EB is equal to ‘0’ representing detection of no error (step S211: no), the host computer 30 performs the regular data writing process discussed above with reference to FIG. 5 (step S200) and terminates this processing routine.

As described above, the host computer 30 reads the value registered in the error detection result storage area EB in the process of writing data into the semiconductor storage device 10. This determines whether the data stored in the semiconductor storage device 10 is matched with the write data and identifies the presence or the absence of any writing error. Even in the event of sudden power shutdown, the host computer 30 of the embodiment can readily detect the occurrence of any writing error of write data (uncompleted data writing) and readily identify a writing request for write data with an error before the power shutdown. The host computer 30 can thus efficiently detect the occurrence of any writing error without performing the time-consuming verification by comparison between the data stored in the memory array 100 and the data as writing object obtained by the host computer 30. Upon detection of any writing error, the host computer 30 makes another trial for writing the write data. Upon detection of no writing error, on the other hand, the host computer 30 immediately restarts the writing operation for writing the required write data.

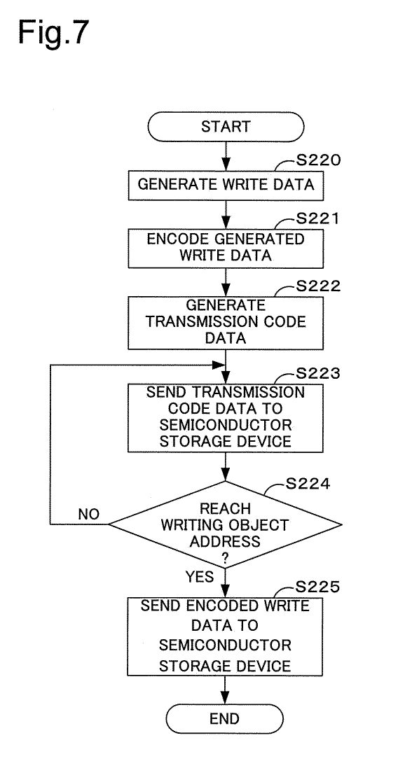

FIG. 7 is a flowchart showing a processing routine executed for quick data writing at a desired address in the host computer at the time of access control for the semiconductor storage device in the embodiment.

The host computer 30 generates a write data array based on writing object data (step S220) and encodes the generated write data array (step S221) according to the procedure discussed above. The host computer 30 subsequently generates a transmission code data (step S222). According to a concrete procedure, the data generator 31 generates a data array including an ID of a desired semiconductor storage device 10 as a writing destination, a write command, and a command parity bit. The encoding circuit 32 then stores an opposite value to the parity value computed from the write data, that is, ‘1’ opposite to the computed parity value ‘0’ or ‘0’ opposite to the computed parity value ‘1’, as a data parity bit into the data array.

According to the above measure (2) of identifying permission or prohibition of data writing in each writing cycle in the semiconductor storage device 10, transmission of this transmission code data skips data writing at the corresponding addresses (rows). The memory array 100 of this embodiment is the sequential access-type memory and requires successive data writing from lower addresses to upper addresses when a desired address is an upper address. Transmission of the transmission code data for intentional inexecution of data writing up to a desired address to the semiconductor storage device 10 ensures quick data writing at the desired address without performing the writing operation for the lower addresses. Namely the transmission code data is used for transmission of an address.

The host computer 30 sends the generated transmission code data to the semiconductor storage devices 10 (step S223). According to a concrete procedure, the host computer 30 outputs the generated transmission code data to the data signal line DL to send the transmission code data to the respective semiconductor storage devices 10 including the desired semiconductor storage device identified as the writing destination, while outputting the clock signal corresponding to a writing completion address to the clock signal line CL. The host computer 30 repeatedly outputs the transmission code data, until reaching a writing object address (step S224: no). Namely the transmission code data is continuously sent until completion of transmission of the transmission code data corresponding to one previous row immediately before a specific row including the writing object address in the memory array 100.

When reaching the writing object address (step S224: yes), the host computer 30 sends a correctly encoded write data packet to the semiconductor storage device 10 (step S225) and terminates this processing routine. At this moment, the host computer 30 outputs an encoded write data packet to be written in the specific row including the writing object address to the data signal line DL, instead of the transmission code data.

As described above, the host computer 30 desirably shortens the time required for writing the write data into the semiconductor storage device 10. Transmission of the transmission code data as intentionally erroneous write data skips data writing at addresses prior to a desired address (more precisely, prior to a specific row including the desired address) and thereby shortens the time required for an access to the desired address in the sequential access-type memory. Non-writing of data at addresses other than the writing object address desirably avoids the potential failure or damage of the existing data stored in the memory array 100 and effectively enhances the reliability of the data stored in the memory array 100.

### [Structure of Liquid Container]

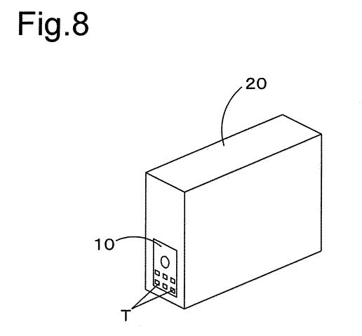

FIG. 8 is an explanatory view showing one example of a liquid container. A liquid container 20 includes the semiconductor storage device 10 discussed above, as well as a liquid reservoir assembly (not shown). The liquid container 20 is, for example, an ink cartridge or another print recording material container. The semiconductor storage device 10 receives control signals from a printing apparatus constructed as the host computer 30 via terminals T and sends read data and an error detection signal to the printing apparatus. One or multiple liquid containers 20 may be provided in the printing apparatus.

The semiconductor storage device 10 provided in the liquid container 20 may characteristically store irreversible data on a liquid level, for example, only liquid level increasing data or liquid level decreasing data. In this application, wrong data is not correctable by later data writing. For example, it is not allowed to write data for decreasing the increased data. There is accordingly a high demand for preventing wrong data writing. The semiconductor storage device 10 and the liquid container 20 according to this embodiment effectively meet this demand.

### Second Embodiment

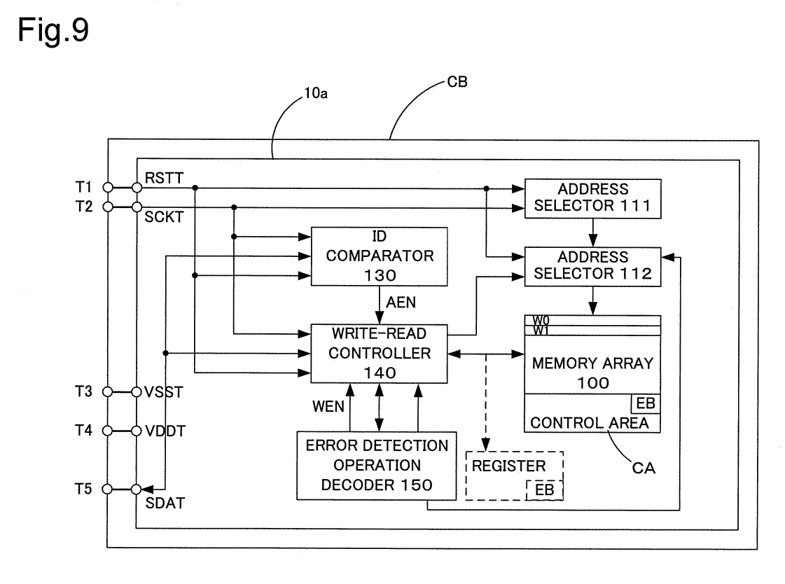

A semiconductor device and an access method for the semiconductor device are described below as a second embodiment of the invention with reference to FIGS. 9 through 14. FIG. 9 is a functional block diagram showing the internal structure of a semiconductor device in a second embodiment of the invention.

A semiconductor device 10a of this embodiment includes a memory array 100, a clock counter 111, an address selector 112, an ID comparator 130, a read-write controller 140, and an error detection operation decoder 150. The combination of the write-read controller 140 with at least the ID comparator 130 and the error detection operation decoder 150 may be referred to as a memory controller in the description herein. In the structure of this embodiment, the semiconductor device 10a is mounted on a circuit board CB. A reset signal terminal RSTT, a clock signal terminal SCKT, power supply terminals VDDT and VSST, and a data signal terminal SDAT of the semiconductor device 10a are electrically connected with respective external terminals T, an external reset signal terminal T1, an external clock signal terminal T2, external power supply terminals T3 and T4, and an external data signal terminal T5, of the circuit board CB. The respective circuits in the semiconductor device 10a of the second embodiment that have the like structures and functions to those of the corresponding circuits in the semiconductor storage device 10 of the first embodiment are expressed by the like numerals and symbols and are not specifically described here. A data array transmitted between the semiconductor device 10a and a printing apparatus (discussed later) is similar to the data array of the first embodiment, unless otherwise specified.

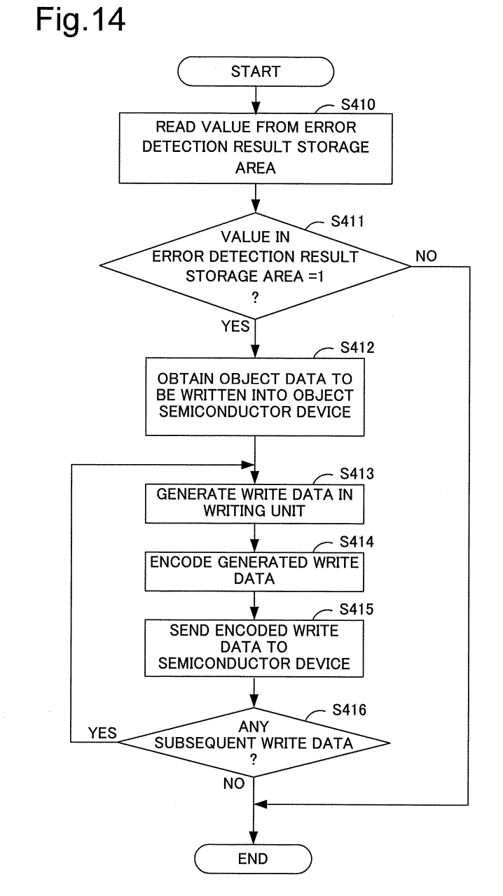

The memory array 100 (storage element) represents a storage area having the EEPROM characteristics of enabling data to be electrically written and erased. The memory array 100 includes a number of memory cells, each having the capacity for storing 1-bit information. In the memory array 100, identification information ID is stored at a first row W0, and a row W1 and subsequent rows following the row W0 are either writing object rows or reading object rows. The memory array 100 has memory cells for eight addresses (memory cells of 8-bit data capacity) on each line selected by a row selection signal output from the address selector 112. The eight memory cells selected by one row selection signal are the unit of each simultaneous writing operation or reading operation. In the structure of this embodiment, the memory array 100 has thirty two rows and is capable of totally storing data of 32 words×8 bits (=256 bits). A control area CA is provided at specified rows in the memory array 100. The control area CA stores pieces of information for defining the area characteristics of the memory array 100, for example, control information (lock information) for defining a certain line as a read only line that does not allow data writing and error detection result information representing a result of error detection whether an error is detected or not. The error detection result information is registered in an error detection result storage area EB in the control area CA. The error detection result storage area EB is, for example, a 1-bit area. In response to detection of an error either in identification information and command data or in write data by the error detection operation decoder 150, a value ‘1’ is recorded into the error detection result storage area EB via the write-read controller 140. In response to detection of no error in identification information and command data or in write data by the error detection operation decoder 150, on the other hand, a value ‘0’ is recorded into the error detection result storage area EB via the write-read controller 140. The value in the error detection result storage area EB is read out in response to an error detection result read command and is reset to ‘0’ on completion of the access in response to the error detection result read command. The details of this procedure will be discussed later with reference to FIG. 14.

In the memory array 100, word lines and bit (data) lines are connected to the respective memory cells. The data writing procedure into a certain memory cell as a writing destination selects a corresponding word line (row) including the certain memory cell, applies a voltage to the selected word line, and applies a write voltage into a corresponding bit line including the certain memory cell, so as to write data into the certain memory cell. In the case of collectively writing data into memory cells on a selected row, the procedure applies a write voltage corresponding to object write data to all the bit lines connecting with the selected row. The data reading procedure from a certain memory cell as a reading destination selects a corresponding word line (row) including the certain memory cell, connects a corresponding bit line including the certain memory cell with the write-read controller 140, and read data (1 or 0) from the certain memory cell based on detection or no detection of electric current.

The clock counter 111 is connected with the reset signal terminal RSTT, the clock signal terminal SCKT, the write-read controller 140, and the address selector 112. The clock counter 111 receives a write enable signal WEN output from the error detection operation decoder 150 as discussed later. The count on the clock counter 111 is reset to an initial value by setting 0 (or a low level) to a reset signal input via the reset signal terminal RSTT. The clock counter 111 counts the clock pulse number (increments the count or decrements the count) synchronously with a fall of each external clock pulse input via the clock signal terminal SCKT after setting 1 to the reset signal (cancellation of the reset state). The clock counter 111, however, does not count any clock pulse for transmission of a command parity bit (CP bit) from the host computer. After input of the write enable signal WEN, the clock counter 111 skips counting one clock pulses out of every nine clock pulses. When the semiconductor device 10a receives each write data packet, the clock counter 111 skips counting a clock pulse corresponding to head data of the write data packet. Namely the number of clock pulses counted by the clock counter 111 is eight among nine clock pulses input in the course of receiving a 9-bit write data packet. The clock counter 111 is designed to count the number of addresses corresponding to the capacity of the memory array 100. Since the memory array 100 of this embodiment has the capacity of 256 bits, the clock counter 111 has the 8-bit capacity to count addresses 0 to 255 in the memory array 100. The initial value of the clock counter 111 may be any value relating to selection of a head row (row W0) with storage of the identification information ID and is typically equal to 0.

The address selector 112 is connected with the reset signal terminal RSTT, the clock counter 111, the write-read controller 140, the error detection operation decoder 150, and the memory array 100. The address elector 112 outputs a column selection signal and a row selection signal to the memory array 100, in response to the count input from the clock counter 111 and a control signal input from the write-read controller 140. The address selector 112 selects one row among thirty two rows by the upper 5 bits of the input 8-bit count and selects one column among eight columns by the lower 3 bits of the input 8-bit count. In the case of collectively reading data from or writing data into a specified row, the address selector 112 outputs a column selection signal for selecting all the columns on the specified row to the memory array 100. The row selection signal is used to directly select (specify) a desired row in the memory array 100. The address selector 112 has a table describing a read object row corresponding to each clock pulse during input of a count for specifying a head row from the clock counter 111 (during input of eight clock pulses in this embodiment) after input (or detection) of a reset cancellation signal. For example, as the address selector 112 selects the row WO corresponding to a count value ‘0’ after cancellation of the reset state, the write-read controller 140 reads data from the row WO. Count values ‘1’ through ‘7’ all specify the row W0. The address selector 112 refers to the table and selects the row for storage of the lock information and the row including the error detection result storage area EB for storing the result of error detection corresponding to a count value ‘2’. The write-read controller 140 then reads out data from these elected rows. The address selector 112 also receives an error detection signal from the error detection operation decoder 150. In response to reception of the error detection signal, the address selector 112 outputs a row selection signal to the memory array 100 to specify the row including the error detection result storage area EB. The write-read controller 140 then records the result of error detection into the specified row including the error detection result storage area EB. Although a certain memory cell is specified as a writing destination or a reading destination by counting the clock pulses, this arrangement ensures a quick access to a memory cell at a desired address without counting up (or counting down) to read or write data from or into the memory cell.

The semiconductor device 10a may be designed to have a register 115 shown by a phantom line in FIG. 9. The error detection result storage area EB may be provided in the register 115 to store the result of error detection.

The ID comparator 130 is connected with the clock signal terminal SCKT, the data signal terminal SDAT, and the reset signal terminal RSTT and identifies whether identification data included in an input data array input via the data signal terminal SDAT is identical with identification information ID stored in the memory array 100. According to a concrete procedure, the ID comparator 130 obtains data of first 3 bits, which is included in an operation code input after a reset signal RST for cancelling the initial state of the semiconductor device 10a, via the data signal terminal SDAT. Simultaneously the ID comparator 130 inputs 3-bit data corresponding to identification data on the head line in the memory array 100, which is read from the memory array 100 by the write-read controller 140, from the write-read controller 140. The ID comparator 130 successively compares the 3-bit data obtained via the data signal terminal SDAT with the 3-bit data obtained from the write-read controller 140. In the case of perfect matching of the two 3-bit data, the corresponding semiconductor device 10a identifies itself as a selected semiconductor device 10a by a host computer among one or multiple semiconductor devices 10a bus-connected with the host computer. The ID comparator 130 then outputs an access enable signal AEN to the write-read controller 140. In the case of mismatching of the 3-bit data obtained via the data signal terminal SDAT with the 3-bit data obtained from the write-read controller 140, on the other hand, the ID comparator 130 does not output the access enable signal AEN. The corresponding semiconductor device 10a accordingly does not perform either a reading operation or a writing operation and is returned to the reset state in response to input of the reset signal RST (RST=0 or low).

The write-read controller 140 is connected with the memory array 100, the ID comparator 130, the error detection operation decoder 150, the clock signal terminal SCKT, the data signal terminal SDAT, and the reset signal terminal RSTT. The write-read controller 140 reads identification data from the memory array 100 synchronously with clock pulses input after cancellation of the reset state and successively outputs the identification data to the ID comparator 130. The write-read controller 140 waits for input of the access enable signal AEN from the ID comparator 130 and the write enable signal WEN from the error detection operation decoder 150 and changes over the internal operation of the semiconductor device 10a to the writing operation. In the case of no input of the write enable signal WEN, the write-read controller 140 keeps the reading operation of the semiconductor device 10a. The write-read controller 140 reads out and temporarily stores the lock information or the information on the area characteristics of the memory array 100 from specific rows in the control area CA selected by the address selector 112, synchronously with 1^{st} through 7^{th} clock pulses of the clock signal input via the clock signal terminal SCKT after input of the reset signal for cancellation of the reset state.

In the case of an access for writing, the write-read controller 140 refers to the lock information and determines whether an object area for the access is a writable area. When the object area for access is a writable area, the write-read controller 140 performs a writing operation in the writable area. When the object area for access is not a writable area, on the other hand, the write-read controller 140 does not perform a writing operation. The write-read controller 140 has an 8-bit register (not shown) for temporarily storing 8-bit write data after an operation code included in write data that is input from the data signal terminal SDAT via a connecting input signal line, as well as a register (not shown) for storing data read from the memory array 100.

A data array (MSB) input via the input signal line from the data signal terminal SDAT is sequentially stored in the 8-bit register until all 8 bits are occupied. When all 8-bits are occupied, the stored 8-bit data is written into the memory array 100.

At a power-ON time of the semiconductor device 10a or at a reset time when the semiconductor device 10a falls into the reset state, the write-read controller 140 sets the data transfer direction relative to the memory array 100 to a reading direction, while making the input signal line connecting with the data signal terminal SDAT high impedance to prohibit data transfer relative to the data signal terminal SDAT. This state is kept until analysis of the R/W (read/write) command by the error detection operation decoder 150. Data of first 4 bits in a data array input via the data signal terminal SDAT after input of the reset signal are not written into the memory array 100, while data stored in first 4 bits in the memory array 100 are transferred to the ID comparator 130. The first 4 bits in the memory array 100 are thus kept in a read only state.

The write-read controller 140 waits for both input of the write enable signal WEN from the error detection operation decoder 150 and input of the access enable signal AEN from the ID comparator 130 and starts a writing operation. In the case of no input of the write enable signal WEN from the error detection operation decoder 150, on the contrary, the write-read controller 140 waits for input of the access enable signal AEN from the ID comparator 130 and starts a reading operation.

When the write-read controller 140 receives a first write data packet, the clock counter 111 outputs a count value for specifying a next row (row W1) subsequent to the row W0 to the address selector 112. The write-read controller 140 then transfers the first write data packet to the memory array 100 and writes the first write data packet in the specified row W1 in the memory array 100. The write-read controller 140 repeats this series of processing until completion of receiving and writing all the write data packets sent after the first write data packet from the host computer.

On the occasion of the reading operation, as the clock counter 111 counts the number of external clock pulses, the write-read controller 140 reads data from a specific memory cell or a specific row selected by the address selector 112 based on the count of the clock counter 111 and sends the read data to the host computer.

In the presence of an error in write data, the procedure of this embodiment does not perform the writing operation of the write data into the memory array 100. When an error occurs in a write data array input from a host computer due to, for example, an external noise, the procedure of this embodiment utilizes an error correction encoding technique and does not perform the writing operation of at least the write data array with the error into the memory array 100. This aims to enhance the reliability of data stored in the memory array 100. This function is provided by the error detection operation decoder 150 discussed below.

The error detection operation decoder 150 is connected with the reset signal terminal RSTT, the write-read controller 140, and the address selector 112 via signal lines. The error detection operation decoder 150 obtains read/write control information (5-bit information following the 3-bit ID information) included in data array input via the data signal terminal SDAT, synchronously with 4^{th} through 8^{th} clock pulses after input of the reset signal RST. The error detection operation decoder 150 performs error detection with the input ID information, the read/write control information (R/W command), and a 9^{th} bit or a command parity bit (CP bit) following the 5-bit write-read control information. When a parity value represented by the command parity bit (CP bit) is identical with a parity value computed from the ID information and the read/write control information, the error detection operation decoder 150 identifies the read/write control information as a valid command. When the two parity values are not identical but are different, on the other hand, the error detection operation decoder 150 identifies the write-read control information as an invalid command. When the write-read control information is identified as a valid command and represents a write command, the error detection operation decoder 150 subsequently performs error detection with regard to the input write data array. When the write-read control information is identified as an invalid command or represents a read command, on the other hand, the error detection operation decoder 150 does not perform error detection with regard to the input write data array.

When the input data array is write data, the error detection operation decoder 150 performs error detection for each data packet with each 8-bit write data packet and a subsequent 1-bit data parity bit (DP bit) shown in FIG. 2. When a parity value represented by the data parity bit (DP bit) is identical with a parity value computed from the write data packet, the error detection operation decoder 150 determines that no error arises in the write data packet. When the two parity values are not identical but are different, on the other hand, the error detection operation decoder 150 determines that an error arises in the write data packet. The error detection operation decoder 150 performs such error detection for all the write data packets. The error detection of data with the parity bit is known in the art and is thus not specifically explained here. Upon determination that no error arises in the write data packet, the error detection operation decoder 150 outputs the write enable signal WEN to the write-read controller 140 and writes the value ‘0’ into the error detection result storage area EB. Upon determination that an error arises in the write data packet, on the other hand, the error detection operation decoder 150 does not output the write enable signal WEN and writes the value ‘1’ into the error detection result storage area EB.

According to a concrete procedure, upon detection of an error, the error detection operation decoder 150 outputs an error detection signal to the address selector 112, while outputting an error detection result writing request to the write-read controller 140. In response to reception of the error detection signal, the address selector 112 outputs a row selection single to the memory array 100 to select a specific row including the error detection result storage area EB. The write-read controller 140 generates column data with flag information ‘1’, which represents the occurrence of an error and is to be written in the error detection result storage area EB, and transfers the generated column data to the memory array 100. The value ‘1’ is accordingly written into the error detection result storage area EB. Upon detection of an error in write data, the semiconductor device 10a itself can write the result of error detection into the error detection result storage area EB without depending upon an external command, for example, a command from a printing apparatus 300 discussed below. The corresponding write data packet with the detected error is not written into the memory array 100.

### [Structures of Ink Cartridge and Printing Apparatus]

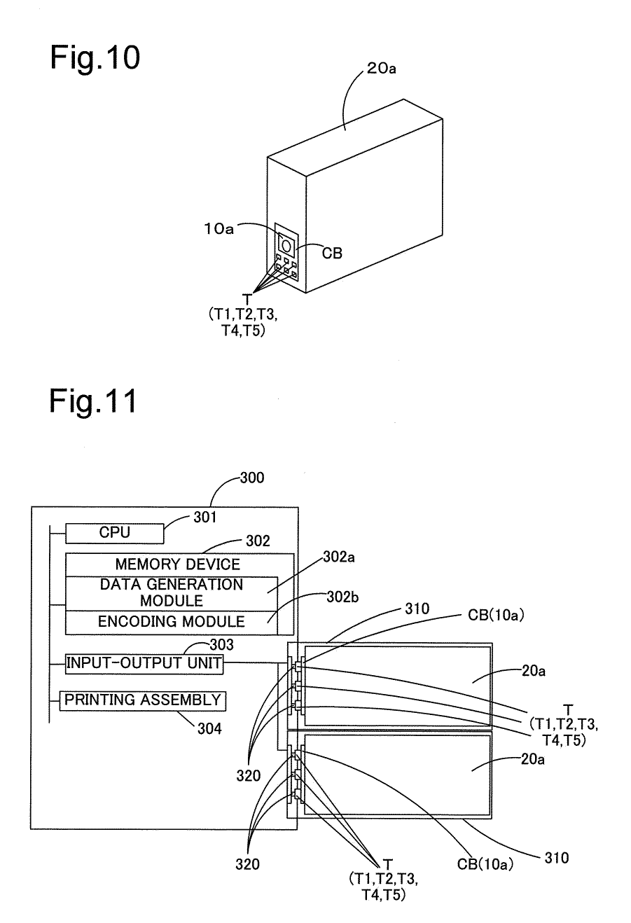

FIG. 10 is an explanatory view showing the schematic structure of an ink cartridge as a liquid container. FIG. 11 is an explanatory view showing the structure of a printing apparatus and connection of the printing apparatus with the ink cartridge in the embodiment. In this embodiment, the printing apparatus has the functions of the host computer. Among various components of the printing apparatus, a printing assembly directly relating to printing operations is not essential for the functions of the host computer.

An ink cartridge 20a has the semiconductor device 10a discussed above and an ink reservoir (not shown). A printing apparatus 300 has an attachment structure 310 designed to hold the ink cartridge 20a attached thereto and an attachment structure terminal assembly 320 designed to connect with external terminals T (T1 through T5) of the ink cartridge 20a. The attachment structure 310 may be located on a carriage (on-carriage type) or may be located at any arbitrary place outside the carriage (off-carriage type).

The printing apparatus 300 includes a central processing unit (CPU) 301, a memory device 302, an input-output unit 303, and a printing assembly 304. The CPU 301, the memory device 302, the input-output unit 303, and the printing assembly 304 are interconnected by internal buses in a bi-directionally communicable manner. The combination of the CPU 301 with the memory device 302 and the input-output unit 303 may thus be referred to as a host computer functional assembly. The memory device 302 has a data generation module 302a configured to generate write data and an encoding module 302b configured to encode data by generating a parity bit for a data array and adding the generated parity bit to the data array. The memory device 302 is designed to temporarily store data read from the semiconductor device 10a and the generated write data. The memory device 302 may delete the write data, which has been sent to the semiconductor device 10a and is stored therein, for example, in response to detection of no writing error as a result of an access to the semiconductor device 10a by an error detection result read command. The data generation module 302a and the encoding module 302b are executed by the CPU 301 to respectively function as a data generator and as an encoder. The data generator and the encoder may alternatively be actualized by the hardware configuration, for example, in the form of a data generation circuit and an encoding circuit. The input-output unit 303 is connected with the attachment structure terminal assembly 320 to send data to the semiconductor device 10a provided in the ink cartridge 20a or to read data from the semiconductor device 10a by an access of the CPU 301 to the semiconductor device 10a. The printing assembly 304 has at least a print head moved in a main scanning direction by a carriage and a feed mechanism designed to feed a printing medium (printing paper) in a sub-scanning direction. The printing assembly 304 operates the print head to eject ink supplied from the ink cartridge 20a and thereby forms a printed image on the printing medium.

The semiconductor device 10a receives control signals from the printing apparatus 300 via the terminals T and sends the read data and the error detection signal to the printing apparatus 300. In the illustrated example of FIG. 11, multiple ink cartridges 20a are attached to the printing apparatus 300. The respective semiconductor devices 10a provided in the multiple ink cartridges 20a share the common signal lines of the printing apparatus and are bus-connected to the common signal lines, for example, a data signal line DL, a clock signal line CL, and a reset signal line RL. Alternatively there may be only one ink cartridge 20a attached to the printing apparatus 300.

### [Operations of Semiconductor Device]

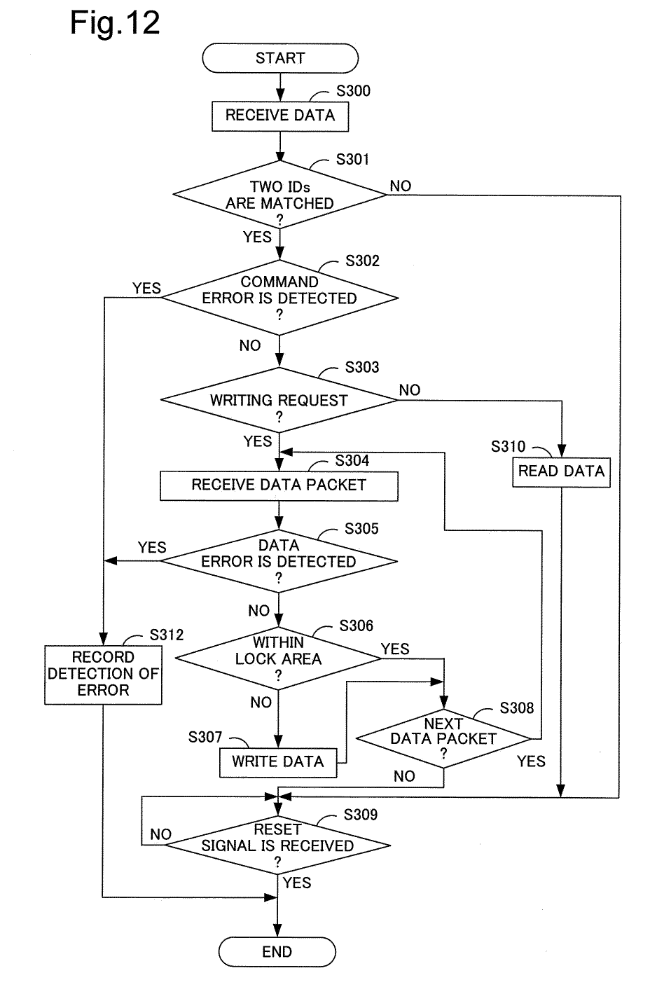

The operations of the semiconductor device 10a in the embodiment are described below with reference to FIG. 12. FIG. 12 is a flowchart showing a processing routine executed in the semiconductor device at the time of access control for the semiconductor device in the embodiment. The following description relates to the system where the multiple ink cartridges 20a are attached to the printing apparatus 300 and the semiconductor device 10a provided in each ink cartridge 20a is bus-connected with the printing apparatus 300.

When receiving a data array from the printing apparatus 300 (step S300), the semiconductor device 10a identifies whether identification information included in the received data array is identical with its own identification information ID (step S301). In the configuration of this embodiment, the semiconductor device 10a provided in each of the ink cartridges 20a is bus-connected with the printing apparatus 300 via the common clock signal line CL, data signal line DL, and reset signal line RL. The data is accordingly sent from the printing apparatus 300 to the respective semiconductor devices 10a. According to the concrete procedure, the ID comparator 130 performs the ID matching by comparing the identification information ID included in the received data array with the identification information ID stored in the memory array 100 as discussed previously. In the case of mismatching of the two IDs (step S301: no), the processing flow proceeds to step S308. In the case of matching of the two IDs (step S301: yes), on the other hand, the semiconductor device 10a performs command error detection (step S302). According to a concrete procedure, the error detection operation decoder 150 compares a command parity bit (CP bit) included in the received data (data array) with the result of a parity operation based on the ID bits and the read/write command bits. The semiconductor device 10a detects no error in the received ID or read/write command in response to matching of the command parity bit with the result of the parity operation, while detecting an error in the received data in response to mismatching. Upon detection of an error (step S302: yes), the semiconductor device 10a writes the value ‘1’ into the error detection result storage area EB of the memory array 100 (step S312) and exits from this processing routine. According to the concrete procedure, the error detection operation decoder 150 performs the writing operation into the control area CA of the memory array 100 via the write-read controller 140 as discussed previously.

Upon detection of no error in the received ID or read/write command (step S302: no), the semiconductor device 10a determines whether there is a request for writing the receive data (step S303). According to the concrete procedure, the error detection operation decoder 150 analyzes the read/write command bits included in the received data array and identifies whether the analyzed read/write command bits represent a writing request or a reading request as described previously. In the case of matching of the two IDs, the ID comparator 130 sends the access enable signal AEN to the write-read controller 140. In the configuration of this embodiment, the ID comparator 130 sends the access enable signal AEN to the write-read controller 140. Alternatively the ID comparator 130 may send the access enable signal AEN to the error detection operation decoder 150. In the latter case, the error detection operation decoder 150 interprets the read/write command bits on reception of the access enable signal AEN.

Upon determination that there is no request for writing the received data but a reading operation is required (step S303: no), the semiconductor device 10a reads desired data from the memory array 100 (step S310) and exits from the processing routine (terminates the series of processing with regard to the current access). The write-read controller 140 reads the desired data from the memory array 100 according to the procedure discussed above.

Upon determination that there is a request for writing the received data (step S303: yes), on the other hand, the semiconductor device 10a receives a write data packet (step S304) and detects an error of the data array if any (step S305). According to the concrete procedure, the error detection operation decoder 150 compares the data parity bit included in the received data array with the result of parity operation based on the write data and detects no error in the received data in response to matching of the command parity bit with the result of the parity operation, while detecting an error in the received data in response to mismatching as explained previously.

In response to detection of no error (step S305: no), the semiconductor device 10a identifies whether the address (area) specified as the writing destination is within the lock area (step S306). According to the concrete procedure, the right-read controller 140 obtains the lock information described in the control area CA of the memory array 100 and determines whether the area specified as the writing destination is a write prohibition area (read only area) where data writing is restricted as discussed previously. Upon determination that the area specified as the writing destination is not within the lock area (step S306: no), the semiconductor device 10a writes the received data into the memory array 100 (step S307). According to the concrete procedure, the error detection operation decoder 150 sends the write enable signal WEN to the write-read controller 140, and the write-read controller 140 writes the received 8-bit data at a specific address (row) in the memory array 100 selected by the address selector 112 as discussed previously.

After data writing, the semiconductor device 10a determines whether there is still any write data packet to be processed (step S308). When there is no more write data packet to be processed (step S308: no), the semiconductor device 10a waits for input of the reset signal (0) for making the semiconductor device 10a fall into the reset state (step S309: no). The semiconductor device 10a terminates this processing routine, in response to input of the reset signal (0) (step S309: yes). When there is still any write data packet to be processed (step S308: yes), the processing flow returns to step S304. In response to detection of an error (step S305: yes), the semiconductor device 10a writes the value ‘1’ into the error detection result storage area EB of the memory array 100 (step S312) and exits from this processing routine. According to the concrete procedure, the error detection operation decoder 150 performs the writing operation into the memory array 100 via the write-read controller 140 as discussed previously.

Upon determination that the area specified as the writing destination is within the lock area (step S306: yes), the semiconductor device 10a determines whether there is still any write data packet to be processed (step S308). When there is still any write data packet to be processed (step S308: yes), the processing flow returns to step S304. When there is no more write data packet to be processed (step S308: no), on the other hand, the processing flow proceeds to step S309.

In the case of detection of an error at step S305, one of the following available measures may be adopted for subsequent data writing:

(1) On detection of an error, the procedure accepts no subsequent writing request.

(2) On detection of an error, the procedure prohibits a currently processed write data packet with the detected error from being written but accepts subsequent writing requests.

(3) On detection of an error, the procedure allows a currently processed write data packet with the detected error to be tried again for data writing.

The concrete procedures and the advantages of the respective measures have been described previously in the first embodiment and are thus not specifically explained here.

As discussed above, the semiconductor device 10a of the embodiment does not perform a writing operation into the memory array 100 on detection of an error in received write data. This arrangement desirably enhances the reliability of data stored in the semiconductor device 10a.

The semiconductor device 10a has the error detection result storage area EB and thus readily determines whether the data stored in the memory array 100 is identical with the object data to be written by the host computer, without performing actual verification by comparison between the write data and the existing data stored in the memory array 100. Even in the event of sudden power shutdown, the semiconductor device 10a of the embodiment can readily identify a writing request for write data with an error before the power shutdown. When the value stored in the error detection result storage area EB represents detection of an error in write data, the semiconductor device 10a immediately starts the writing operation for all the write data without performing the time-consuming verification. When the value stored in the error detection result storage area EB represents detection of no error in write data, the semiconductor device 10a restarts the writing operation for only the remaining unprocessed write data.

### [Operations of Host Computer]

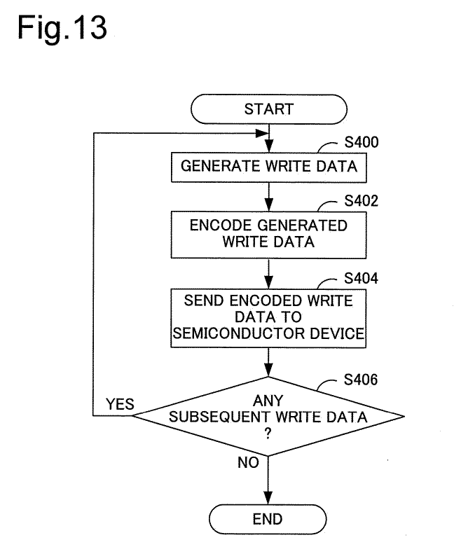

FIG. 13 is a flowchart showing a processing routine executed in the host computer at the time of write access to the semiconductor device in the embodiment. In the description hereafter, a printing apparatus is used as the host computer. The printing apparatus 300 generates write data, which is to be sent to the semiconductor device 10a in a current access for writing, based on writing object data stored in the memory device 302 (step S400). In this embodiment, each writing unit represents transmission of a 1-byte write data array corresponding to one specific row of the memory array 100 selected by the row selection signal. According to a concrete procedure, the data generation module 302a generates the object data to be written in the form of a data array including identification information ID for identifying the semiconductor device 10a as a writing destination, a write command, and data packets as a writing object.

The printing apparatus 300 subsequently encodes the generated write data (step S402). According to a concrete procedure, the encoding module 302b utilizes the identification information ID and the read/write command to generate a command parity bit, utilizes each write data packet to generate a data parity bit, and inserts the command parity bit at a 9^{th} bit and the data parity bit at an 18^{th} bit from the head in the generated data array, so as to encode the data array.

The printing apparatus 300 outputs the encoded write data array to the data signal line DL and sends the encoded write data array to the respective semiconductor devices 10a including the desired semiconductor device identified as the writing destination (step S404). The printing apparatus 300 then determines whether there is any write data to be written in a next row of the memory cell in the desired semiconductor device (step S406). When there is no more write data (step S406: no), the printing apparatus 300 exits from this processing routine.

When there is still any write data to be written (step S406: yes), the printing apparatus 300 returns to step S300 to generate next write data and repeats the processing of steps S400 to S406.

As described above, the printing apparatus 300 sends the encoded write data to the semiconductor device 10a, and the semiconductor device 10a verifies the encoded write data. This arrangement effectively prevents write data with an error to be written into the semiconductor device 10a. Even when the semiconductor device 10a detects an error of data at step S305, the printing apparatus 300 does not check the detected error in the course of data writing operation and continues data writing without interruption. In the configuration of this embodiment, the printing apparatus 300 outputs the error detection result read command for checking the detected error to the semiconductor device 10a on completion of the access for writing, in order to obtain the value stored in the error detection result storage area EB. When the value ‘1’ representing detection of an error is registered in the error detection result storage area EB, the data writing process for the write data with the detected error is performed again.

FIG. 14 is a flowchart showing a processing routine executed with reference to the error detection result in the printing apparatus at the time of access to detect an error representing a failure of writing into the semiconductor device due to a data error.

The following describes access control performed by the printing apparatus 300 based on the error detection result. This processing routine is executed in response to transmission of the error detection result read command explained previously. The printing apparatus 300 sends the error detection result read command to a specific semiconductor device 10a that has made the write access. According to a concrete procedure, the printing apparatus 300 outputs the identification information ID of the specific semiconductor device 10a that has made the write access and the command (error detection result read command) to the data signal line DL. Among all the semiconductor devices 10a that receive the command and the identification information ID, a certain semiconductor device 10a having the matching identification information ID that is identical with the identification information ID of the specific semiconductor device 10a analyzes the received command via the error detection operation decoder 150. Based on the result of the analysis representing the error detection result read command, the certain semiconductor device 10a reads out the value stored in the error detection result storage area EB via the write-read controller 140 and the read value of the error detection result storage area EB to the printing apparatus 300. The printing apparatus 300 accordingly obtains the value of the error detection result storage area EB (step S410). As described previously, the semiconductor device 10a of the embodiment makes access to the error detection result storage area EB in the control area CA synchronously with clock pulses after the reset operation. The printing apparatus 300 can thus immediately obtain the result of error detection. When the error detection result storage area EB is provided in the register 115 outside the memory array 100, the printing apparatus 300 makes access to the register 115 to obtain the error detection result. In response to reception of the error detection result read command, a certain semiconductor device 10a having the mismatching identification information ID that is different from the received identification information ID determines whether the value ‘1’ representing detection of an error is registered in the own error detection result storage area EB. When the registered value is ‘1’, the certain semiconductor device 10a updates the value to ‘0’ in the error detection result storage area EB and terminates the series of processing.

The printing apparatus 300 identifies whether the value registered in the error detection result storage area EB is equal to ‘1’ (step S411). When the value in the error detection result storage area EB is equal to ‘1’ representing detection of an error (step S411: yes), the printing apparatus 300 obtains all writing object data stored in the memory device 312 or all the data used for the previous writing process corresponding to all the writable areas in the memory array 100 (step S412). When the previous write data remains in the memory device 312, the remaining previous write data may be used. Alternatively the data generation module 302a may regenerate the previous write data. The data corresponding to the writable area is equivalent to writable data and is, for example, data relating to information on a liquid level (either a remaining amount or a consumed amount of a liquid) or a frequency of attachment of an ink cartridge to the printing apparatus 300 (frequency of contacts between the semiconductor device 10a and the printing apparatus 300).

The printing apparatus 300 makes access to the semiconductor device 10a in the same manner as the regular access for writing discussed previously with reference to FIG. 13. The printing apparatus 300 generates a command parity bit based on the identification information ID and the read/write (R/W) command and sends the identification information ID, the read/write command, and the command parity bit to the semiconductor device 10a. The printing apparatus 300 then generates write data (write data packets) in the writing unit or in the byte unit (step S413). The printing apparatus 300 subsequently generates a data parity bit based on a generated write data packet, inserts the generated data parity bit at the specified position mentioned above to encode the write data packet (step S414), and sends the encoded write data packet to the semiconductor device 10a (step S415). The detailed procedures of the respective steps have previously been described with reference to FIG. 12 and are thus not specifically explained here.

When there is any subsequent write data (step S416: yes), the processing flow returns to step S413. The printing apparatus 300 repeats the processing of steps S413 to S415 until completion of transmission of all the write data packets. When there is no subsequent write data (step S416: no), the printing apparatus 300 terminates this processing routine.

When the value in the error detection result storage area EB is equal to ‘0’ representing detection of no error (step S411: no), the printing apparatus 300 terminates this processing routine.

As described above, the printing apparatus 300 reads the value registered in the error detection result storage area EB in the process of writing data into the semiconductor device 10a. This determines whether the data stored in the semiconductor device 10a is matched with the write data and identifies the presence or the absence of any writing error. Upon detection of any writing error, the printing apparatus 300 makes another trial for writing the write data. Upon detection of no writing error, on the other hand, the printing apparatus 300 immediately restarts the writing operation for writing the required write data.

Other Aspects

(1) The respective embodiments discussed above adopt the encoding technique using the parity check. This is, however, neither essential nor restrictive. Another encoding technique may also be adopted for the same purpose, for example, CRC (cyclic redundancy checksum), checksum, hash function.

(2) The respective embodiments discussed above use the error detection result storage area EB. The error detection result storage area EB is, however, not essential for preventing write data with a detected error from being written. Namely the semiconductor storage device 10 or the semiconductor device 10b may be constructed without the error detection result storage area EB.

(3) The respective embodiments discussed above use the sequential access-type memory array 100. The similar effects are expected for semiconductor storage devices or semiconductor devices equipped with a random access-type memory array. The writing unit is not restricted to the 1-byte unit but may alternatively be the 1-bit unit. In this application, the encoding process may be performed for several bits including one desired bit. The memory array included in the semiconductor storage device 10 or in the semiconductor device 10a may consist of ferroelectric memory cells. The semiconductor storage device 10 or in the semiconductor device 10a may be equipped with an arithmetic circuit, in addition to the memory array.

(4) In the embodiment discussed above, the multiple semiconductor storage devices 10 are bus-connected with the host computer 30 via the signal lines. The multiple semiconductor storage devices 10 may be star-connected with the host computer 30. Alternatively only one semiconductor storage device 10 may be connected with the host computer 30. In the last case, no identification information is required for identifying the semiconductor storage device. The ID comparator 130 may thus be omitted from the structure of the semiconductor storage device.

(5) The respective embodiments discussed above use the 1-bit area as the error detection result storage area EB. Multiple error detection result storage areas EB of the 1-bit capacity may be provided, for example, corresponding to the number of data storage areas (the number of rows) that are updated with use of a liquid container. In this case, the respective error detection result storage areas EB are mapped to the respective rows. This arrangement allows identification of a specific row with failure of data writing even after power shutdown. The procedure then writes only required write data corresponding to the identified row, thus desirably shortening the total time required for data rewriting.

The embodiments and their modified examples discussed above are to be considered in all aspects as illustrative for the better understanding of the invention and not restrictive in any sense. The present invention may be embodied in other specific forms with some modifications, changes, and alterations without departing from the scope or spirit of the main characteristics of the present invention. All changes that come within the meaning and range of equivalency of the claims are to be embraced within their scope.

The present application claims priority from the following Japanese Patent applications, the contents of which are hereby incorporated by reference into this application:

(1) Japanese Patent Application No. 2008-69078 (filed on Mar. 18, 2008); and

(2) Japanese Patent Application No. 2009-50961 (filed on Mar. 4, 2009).

What is claimed is:

1. A liquid container equipped with a storage device, the liquid container comprising:
a storage element configured to store data;
an error detection circuit configured to receive write data as a writing object, which is to be written into the storage element, and detect an error in the received write data; and
a read-write controller configured to control a data reading operation and a data writing operation from and into the storage element and to prohibit the data writing operation of the received write data into the storage element, in response to detection of an error in the received write data by the error detection circuit.

2. The liquid container in accordance with claim 1, further comprising:
an error detection result storage module configured to store a result of error detection.

3. The liquid container in accordance with either one of claims 1 and 2, wherein the storage element is a sequential access-type storage element, and
in the case of detection of an error in the received write data by the error detection circuit, the read-write controller prohibits the data writing operation of subsequently received write data into the storage element.

4. The liquid container in accordance with either one of claims 1 and 2, wherein the storage element is a sequential access-type storage element, and
in the case of detection of an error in the received write data by the error detection circuit, the read-write controller allows the data writing operation of subsequently received write data with detection of no error by the error detection circuit into the storage element.

5. The liquid container in accordance with claim 1, wherein a write command and an error detection code are allocated to the write data, and
the error detection circuit refers to the write command to identify the received write data as the writing object to be written into the storage element, while referring to the error detection code to detect an error in the received write data.

6. A system configured to include a liquid container equipped with a storage device and a computing machine designed to perform a data writing operation and a data reading operation into and from the storage device,
the computing machine comprising:
an error code allocation circuit configured to allocate an error code to data, which is to be written into the storage device, and generate write data; and
a transmission module configured to send the generated write data to the storage device,
the liquid container comprising:
a storage element configured to store data;
an error detection circuit configured to receive the write data and detect an error in the received write data; and
a read-write controller configured to control a data reading operation and a data writing operation from and into the storage element and to prohibit the data writing operation of the received write data into the storage element, in response to detection of an error in the received write data by the error detection circuit.

7. The system in accordance with claim 6, wherein the liquid container further has an error detection result storage module configured to store a result of error detection, and
when the result stored in the error detection result storage module in the liquid container represents detection of an error, the computing machine sends all write data, which are writable into the storage device, to the storage device.

8. The system in accordance with claim 6, wherein the storage element of the liquid container is a sequential access-type storage element,
the error code allocation circuit of the computing machine generates transmission code data with an erroneous code, and
the computing machine sends the generated transmission code data to the storage device until reaching a desired address in the storage device, and sends the write data to the storage device at the desired address in the storage device.

9. An access control method of controlling an access to a storage device included in a liquid container, the access control method comprising:
receiving write data as a writing object, which is to be written into a storage element provided in the storage device, and detecting an error in the received write data; and
prohibiting a data writing operation of the received write data into the storage element, in response to detection of an error in the received write data.

10. A storage device, comprising:
a storage element configured to store data;
an error detection circuit configured to receive write data as a writing object, which is to be written into the storage element, and detect an error in the received write data; and
a read-write controller configured to control a data reading operation and a data writing operation from and into the storage element and to prohibit the data writing operation of the received write data into the storage element, in response to detection of an error in the received write data by the error detection circuit.

11. A circuit board, comprising:
a semiconductor device having: a storage element configured to store data; an error detection circuit configured to receive write data as a writing object, which is to be written into the storage element, and detect an error in the received write data; and a read-write controller configured to control a data reading operation and a data writing operation from and into the storage element and to prohibit the data writing operation of the received write data into the storage element, in response to detection of an error in the received write data by the error detection circuit; and
one or multiple external terminals electrically connected with the semiconductor device.
